(19) United States
(12) Patent Application Publication
(10) Pub. No.: US 2012/0112806 A1
(43) Pub. Date: May 10, 2012

(54) FREQUENCY SYNTHESIZER AND FREQUENCY SYNTHESIZING METHOD

(75) Inventor: Furkan DAYI, Stuttgart (DE)

(73) Assignee: Sony Corporation, Tokyo (JP)

(21) Appl. No.: 13/280,820

(22) Filed: Oct. 25, 2011

(30) Foreign Application Priority Data
Nov. 9, 2010 (EP) 10190562.8

(51) Int. Cl. H03L 7/087

(52) U.S. Cl. 327/145

(57) ABSTRACT

The present invention relates to a frequency synthesizer comprising a main unit and a side unit. The main unit comprises a main phase detector to obtain a main control signal, a main oscillator that generates a main synthesized frequency output signal representing the frequency synthesizer output signal based on said main control signal, and a mixer that mixes said main synthesized frequency output signal with a side synthesized frequency output signal to obtain said mixer output signal. The side unit generates said side synthesized frequency output signal and comprises a frequency signal generation unit that provides a linear frequency sweep signal or a fixed-frequency control signal at a fine frequency resolution from said fixed-frequency side reference signal, and a side oscillator that generates said side synthesized frequency output signal based on said frequency sweep signal or said fixed-frequency control signal.

### CROSS-REFERENCE TO RELATED APPLICATIONS

The present application claims priority of European patent application 10190562.8 filed on Nov. 9, 2010.

### FIELD OF THE INVENTION

The present invention relates to a frequency synthesizer and a corresponding frequency synthesizing method.

### BACKGROUND OF THE INVENTION

Frequency synthesizers are key building blocks of any microwave system. They are found in many modern devices, including radio receivers, mobile telephones, satellite receivers, GPS systems, radars, etc. . . . . There are three main synthesizer architectures, in particular direct analog, direct digital and indirect (Phase Lock Loop) synthesizers. The requirements of the microwave systems are getting tough, so that the known synthesizers cannot fulfil requirements such as phase noise, switching speed, fine resolution, and frequency sweep. Recently, new hybrid architectures were developed which combines direct digital synthesizer (DDS) and phase look loops (PLL) which, however, can also not fulfil all these requirements.

U.S. Pat. No. 7,250,823 discloses a direct digital synthesis (DDS) phase locked loop (PLL) frequency synthesizer and associated methods. The PLL frequency synthesizer includes a phase detector receiving a reference signal, a controlled oscillator (e.g. a voltage controlled oscillator) connected to the phase detector and generating a synthesized frequency output signal based upon the reference signal, a mixer (e.g. an in-phase and quadrature-phase (IQ) modulator) connected to the controlled oscillator, a divider connected between the mixer and the phase detector, and a signal source driving the mixer. The known frequency synthesizer and method have narrow frequency steps (e.g. as low as fractions of a Hertz) while using a relatively high reference frequency to contribute to the phase noise performance. Furthermore, the fine frequency tuning resolution is achieved while also reducing output spurs. However, this frequency synthesizer suffers also from a high division ratio in the feedback loop as the downconversion of the signal can only be as much as the highest frequency output of the DDS. Commercially available DDS circuits are limited mainly to frequencies below 1 GHz. Therefore, the signal frequency after downconversion must be divided again with high numbers in order to reduce the frequency to a frequency in the range of the phase detector frequency. This results in a large phase noise degradation. For millimeter wave frequencies, this frequency synthesizer is thus not applicable because of the high phase noise of the synthesized signal.

### BRIEF SUMMARY OF THE INVENTION

It is an object of the present invention to provide a frequency synthesizer and a corresponding frequency synthesizing method providing improved phase noise, very fine frequency resolution, agile frequency switching and at the same time very good sweep linearity (required e.g. for some radar applications).

According to an aspect of the present invention there is provided a frequency synthesizer comprising:

i) a main unit comprising:

a main phase detector that compares the phase and/or frequency of a mixer output signal received from a main feedback loop of the main unit to the phase of a fixed-frequency main reference signal to obtain a main control signal,

a main oscillator that generates a main synthesized frequency output signal representing the frequency synthesizer output signal based on said main control signal, and

a mixer that mixes said main synthesized frequency output signal with a side synthesized frequency output signal to obtain said mixer output signal, and

ii) a side unit that generates said side synthesized frequency output signal based on a fixed-frequency side reference signal comprising:

a frequency signal generation unit that provide a linear frequency sweep signal or a fixed-frequency control signal at a fine frequency resolution from said fixed-frequency side reference signal, and

a side oscillator that generates said side synthesized frequency output signal based on said frequency sweep signal or said fixed-frequency control signal.

According to a further aspect of the present invention there is provided a corresponding frequency synthesizing method comprising the steps of:

i) in a main loop:

comparing the phase and/or frequency of a mixer output signal received from a main feedback loop of the main loop to the phase of a fixed-frequency main reference signal to obtain a main control signal,

generating a main synthesized frequency output signal representing the frequency synthesizer output signal based on said main control signal, and

mixing said main synthesized frequency output signal with a side synthesized frequency output signal to obtain said mixer output signal, and

ii) in a side loop for generating said side synthesized frequency output signal based on a fixed-frequency side reference signal:

providing a linear frequency sweep signal or a fixed-frequency control signal at a fine frequency resolution from said fixed-frequency side reference signal, and

generating said side synthesized frequency output signal based on said frequency sweep signal or said fixed-frequency control signal.

Preferred embodiments of the invention are defined in the dependent claims. It shall be understood that the claimed frequency synthesizing method has similar and/or identical preferred embodiments as the claimed frequency synthesizer and as defined in the dependent claims.

The present invention is based on the idea to provide two loops, in particular a main loop and a side loop. The main loop (included in a main unit of the frequency synthesizer) includes a mixer so that the frequency division ratio in the feedback loop and also the overall phase noise is decrease. The side loop (included in a side unit of the frequency synthesizer), which is a preferably a DDS/PLL loop, provides a highly linear RF sweep signal, or fixed RF signals with fine frequency resolution (i.e. the frequency difference between stabilized signals can be very close), which RF sweep signal or said fixed RF signals, respectively, is/are mixed within the main loop with the feedback signal of the main loop.

With the present invention a very linear frequency sweep due to the digital frequency generation from the frequency signal generation unit (preferably including a DDS) can be achieved. Further, a higher frequency signal can be generated for a local oscillator input of the mixer (preferably due to the hybrid DDS/PLL loop, i.e. the side loop), because the output frequency of the side loop is not limited to the highest frequency of the DDS as in the architecture known from U.S. Pat. No. 7,250,823. Hence, the RF signal (at the input of the mixer) can be downconverted to lower IF frequencies (at the output of the mixer) leading to a phase noise improvement. Because the output of the frequency signal generation unit (preferably including the DDS) is not connected to the phase detector input in the main loop as in known architectures, a very stable reference frequency, e.g. from an OCXO (Oven-Controlled Crystal Oscillator) can be used for the phase detector input of the main loop. This also leads to a phase noise improvement.

Compared to conventional PLLs, the frequency resolution does not depend on the phase detector frequency, so that the high phase detector frequency is not an issue for the proposed architecture in which the frequency resolution is determined by the DDS.

In still another aspect of the present invention, a frequency synthesizer is presented comprising:

i) a main unit comprising:

a main phase detection means for comparing the phase and/or frequency of a mixer output signal received from a main feedback loop of the main unit to the phase of a fixed-frequency main reference signal to obtain a main control signal,

a main oscillation means for generating a main synthesized frequency output signal representing the frequency synthesizer output signal based on said main control signal, and

a mixing means for mixing said main synthesized frequency output signal with a side synthesized frequency output signal to obtain said mixer output signal, and

ii) a side unit for generating said side synthesized frequency output signal based on a fixed-frequency side reference signal comprising:

a frequency signal generation means for providing a linear frequency sweep signal or a fixed-frequency control signal at a fine frequency resolution from said fixed-frequency side reference signal, and

a side oscillation means for generating said side synthesized frequency output signal based on said frequency sweep signal or said fixed-frequency control signal.

### BRIEF DESCRIPTION OF THE DRAWINGS

These and other aspects of the present invention will be apparent from and explained in more detail below with reference to the embodiments described hereinafter. In the following drawings

FIG. 1 shows a block diagram of a first embodiment of a known hybrid DDS/PLL frequency synthesizer,

FIG. 2 shows a block diagram of a second embodiment of a known hybrid DDS/PLL frequency synthesizer,

FIG. 3 shows a block diagram of a third embodiment of a known hybrid DDS/PLL frequency synthesizer,

FIG. 4 shows a block diagram of a fourth embodiment of a known hybrid DDS/PLL frequency synthesizer,

FIG. 5 shows a block diagram of a first embodiment of a frequency synthesizer according to the present invention,

FIG. 6 shows a block diagram of a second embodiment of a frequency synthesizer according to the present invention,

FIG. 7 shows an exemplary embodiment of a DDS for use in a frequency synthesizer according to the present invention,

FIG. 8 shows an exemplary embodiment of an oscillator for use in a frequency synthesizer according to the present invention,

FIG. 9 shows an exemplary embodiment of a loop filter for use in a frequency synthesizer according to the present invention,

FIG. 10 shows an exemplary embodiment of a phase frequency detector for use in a frequency synthesizer according to the present invention, and

FIG. 11 shows a block diagram of a third embodiment of a frequency synthesizer according to the present invention.

### DETAILED DESCRIPTION OF THE INVENTION

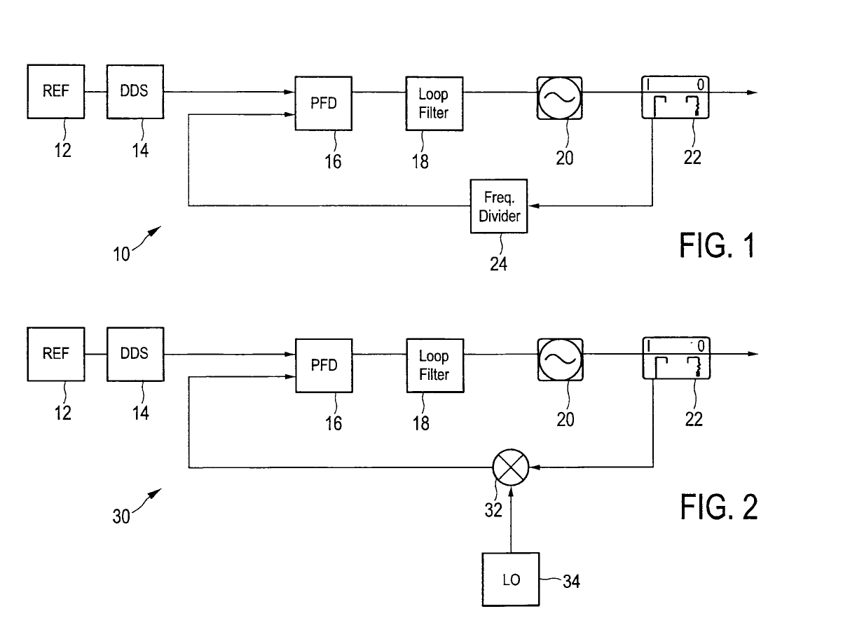

FIG. 1 shows a first embodiment of a hybrid DDS/PLL frequency synthesizer 10 as, for instance, described in Stelzer, A.; Kolmhofer, E.; Scheiblhofer, S., “Fast 77 GHz chirps with direct digital synthesis and phase locked loop”, Microwave Conference Proceedings, 2005, APMC 2005, Asia-Pacific Conference Proceedings, vol. 3, 4-7 Dec. 2005. This frequency synthesizer comprises a DDS (direct digital synthesizer) 14, which receives a reference signal from a reference signal source 12 and which it turn is used as a reference input for a phase detector 16. The phase detector 16 (also called phase frequency detector; PFD detects frequency and phase differences between the reference signal from the DDS 14 and a feedback signal from a feedback loop. A loop filter 18 is coupled to the output of the phase detector 16 for filtering the control signal output from the phase detector 16. A controlled oscillator 20, e.g. a voltage controlled oscillator (VCO), is coupled to the output of the loop filter 18 and generates a synthesized frequency output signal based upon the reference signal. Said synthesized frequency output signal is output by an output unit 22, e.g. a splitter, which also provides the synthesized frequency output signal to a frequency divider 24 in the feedback loop. The frequency divider 24 provides the feedback signal to the phase detector 16.

The output frequency and the RF bandwidth are by a factor N_{D} (frequency division ration in the feedback loop) higher than the DDS generated frequency and bandwidth. Typically, the DDS reference frequency of the generally used (and commercially available) DDS is in the range from hundred MHz to one GHz, and phase detectors operate from some hundred kHz to some hundred MHz. The chosen phase detector frequency in combination with the loop filter dynamics determine the overall dynamical behavior of the frequency synthesizer, i.e. the reachable deviation of a preset ramp. On the one hand, a high divider ratio N_{D} lowers the DDS frequency and increases the RF bandwidth, but on the other hand the phase noise performance of the synthesizer decreases with 20 log (N_{D}). A compromise is therefore necessary.

In this embodiment, the reference frequency source for the phase detector 16, i.e. reference signal source 12 in combination with the DDS 14, has worse phase noise than stable reference source like an OCXO because the DDS 14 contributes to the phase noise. In addition, the high frequency division ratio of the frequency divider 24 degrades the overall phase noise of the frequency synthesizer 10 substantially.

FIG. 2 shows a second embodiment of a hybrid DDS/PLL frequency synthesizer 30 having an offset loop as, for instance, described in Wagner, C.; Feger, R.; Haderer, A.; Fischer, A.; Stelzer, A.; Jager, H., “A 77-GHz FMCW radar using a digital phase-locked synthesizer”, Microwave Symposium Digest, 2008, IEEE MTT-S International, vol. 57, no. 5, pp. 351-354, 15-20 Jun. 2008 and Wagner, C.; Stelzer, A.; Jager, H., “Estimation of FMCW radar system performance using measurement data of a 77-GHz transmitter”, Microwave Conference, APMC 2006, Asia-Pacific, pp. 1701-1704, 12-15 Dec. 2006. This embodiment of the frequency synthesizer 30 is to a large extent identical to the embodiment of the frequency synthesizer 10 shown in FIG. 1. Instead of the frequency divider 24, however, a mixer 32 is used in the feedback loop, said mixer 32 being provided with a mixing frequency from a local oscillator 34, to down-convert the output frequency of the frequency output signal provided by the output unit 22 to the phase detector frequency of the feedback signal provided to the phase detector 16 in order to improve the phase noise. However, the output signal bandwidth is limited (in case of using a broadband oscillator, locking problems will occur because the signal bandwidth does not change after down-conversion process, where the signal can exceed the locking range of the phase detector) and the phase detector reference frequency is created by the DDS 14, which yields worse phase noise compared to a stable reference source like an OCXO, which has the highest frequency stability in crystal oscillators.

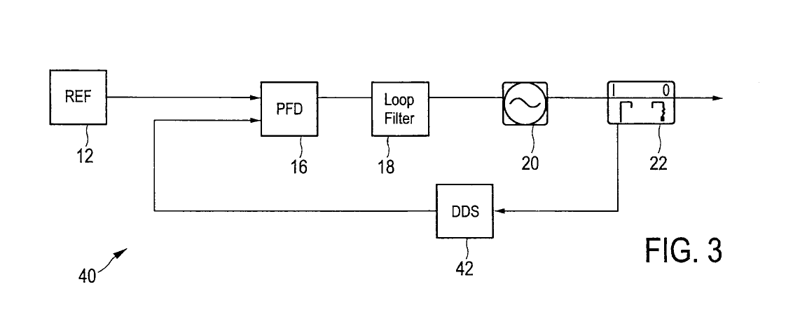

FIG. 3 shows a third embodiment of a hybrid DDS/PLL frequency synthesizer 40 having a fractional loop as, for instance, described in Stelzer, A.; Kolmhofer, E.; Scheiblhofer, S., “Fast 77 GHz chirps with direct digital synthesis and phase locked loop”, Microwave Conference Proceedings, 2005, APMC 2005, Asia-Pacific Conference Proceedings, vol. 3, 4-7 Dec. 2005. Compared to the embodiment of the frequency synthesizer 10, 30 shown in FIG. 1 the DDS 42 is located in the feedback loop rather than between the reference signal source 12 and the phase detector 16. There is no need for an additional clock signal for the DDS 42. In addition, as reference for the phase detector 16 the reference signal provided from the reference signal source 12, which has a very good phase noise, is used. However, this embodiment has a non-linearity problem during a continuous frequency sweep. Further, also the oscillator frequency of the oscillator 20 must be divided at least to the maximum DDS input frequency, which contributes to the phase noise of the synthesized frequency output signal.

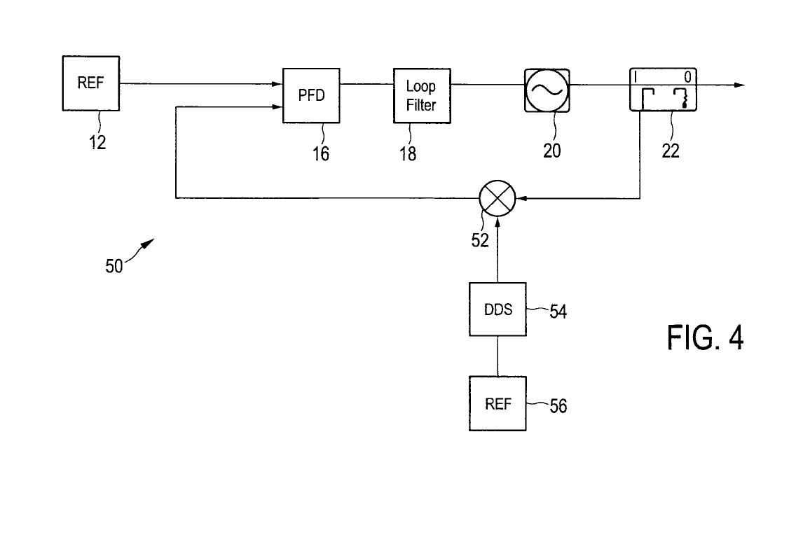

FIG. 4 shows a fourth embodiment of a hybrid DDS/PLL frequency synthesizer 50 having an offset loop as, for instance, described in the above mentioned U.S. Pat. No. 7,250,823. In this embodiment an offset loop is provided, where a DDS 54, provided with a DDS reference signal from a DDS reference signal source 56, is used to provide a local oscillator signal for a mixer 52 provided in the feedback loop. In this case, a reference signal source 12 with good phase noise can be used, and a linear continuous frequency sweep can be generated. However, the chirp bandwidth is limited and frequency dividers (not shown) with high division ratios are generally needed in the feedback loop to realize the phase detector frequency. Because the DDS 54 generally has output frequencies only up to approximately 500 MHz, which will be local oscillator signal of the mixer 52 in this case, the microwave oscillator signal of the oscillator 20 can only be down-converted to a frequency that is approximately 500 MHz below the RF input of the mixer 52. Therefore, there is no phase noise improvement achievable with this embodiment.

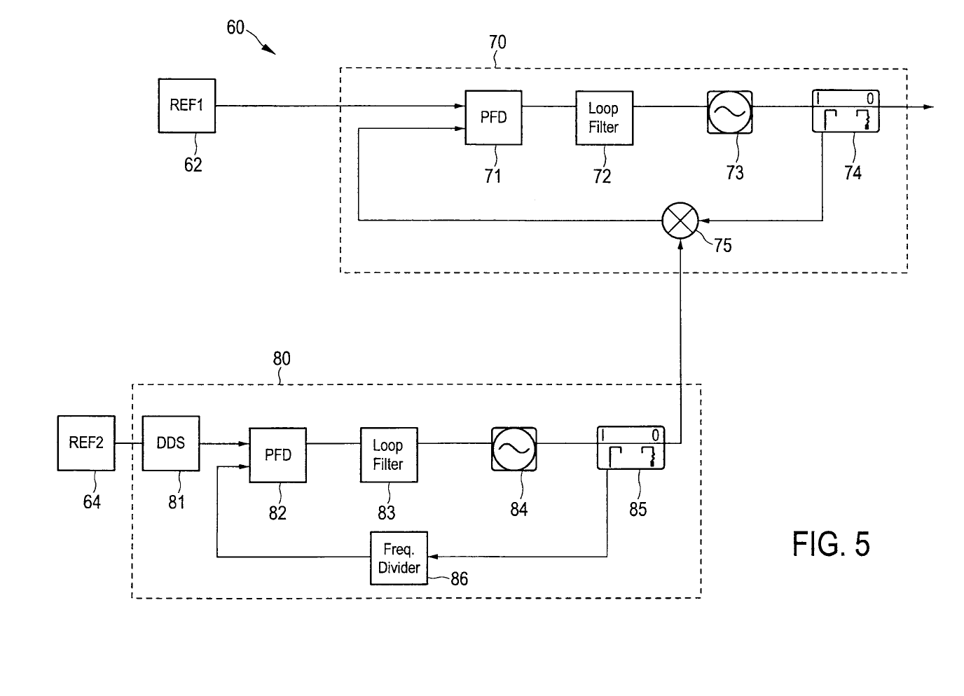

FIG. 5 shows a block diagram of a first embodiment of a frequency synthesizer 60 according to the present invention. This frequency synthesizer 60 comprises two units (also referred to as two loops), in particular a main unit 70 and a side unit 80.

The main unit 70 comprises a main phase detector 71 that compares the phase and/or frequency of a mixer output signal received from a main feedback loop of the main unit 70 to the phase of a fixed-frequency main reference signal received from a (external or internal) main reference signal source 62 to obtain a main control signal. This main control signal is filtered by a main loop filter 72. Based on the (filtered) main control signal a main oscillator 73 generates a main synthesized frequency output signal representing the frequency synthesizer output signal that is outputted by a main output unit 74. A mixer 75 provided in the feedback loop mixes said main synthesized frequency output signal with a side synthesized frequency output signal to obtain said mixer output signal provided to the main phase detector 71.

The side unit 80 comprises a direct digital synthesizer (DDS) 81 (generally also called frequency signal generation unit) that generates a DDS signal (generally a linear frequency sweep signal or a fixed-frequency control signal at a fine frequency resolution) from a fixed-frequency side reference signal received from a (external or internal) side reference signal source 64. Said DDS signal is provided as reference signal to a side phase detector 82 that compares the phase and/or frequency of a frequency divider output signal received from a side feedback loop of the side unit 80 to the phase of the DDS signal to obtain a side control signal. This side control signal is filtered by a side loop filter 83. Based on the (filtered) side control signal a side oscillator 84 generates said side synthesized frequency output signal that is provided to the mixer 75 of the main unit 70. A side frequency divider 86 frequency divides the side synthesized frequency output signal to obtain said frequency divider output signal provided to the side phase detector 82.

Due to the use of the mixer 75 in the main feedback loop of the main unit 70 frequency division ratio in the main feedback loop and also the overall phase noise are decreased. The side unit 80 substantially represents a DDS/PLL loop which provides a highly linear RF frequency which is mixed within the main feedback loop of the main unit 70 with the feedback signal of the main unit 70. As a reference signal source 62 of the main unit 70 high frequency (i.e. a frequency that can be handled by the main phase detector 71), low phase noise reference sources like OCXOs can be used. A high phase detector frequency maintains a low phase noise. Contrary to conventional PLLs, the frequency resolution does not depend on the phase detector frequency, so that a high phase detector frequency is not an issue for the proposed frequency synthesizer since the frequency resolution is determined by the DDS 81.

Unlike the architecture shown in FIG. 4, the output frequency of the side unit 80 including the DDS/PLL loop (i.e. the local oscillator input of the mixer 75) is not limited to the highest frequency of the DDS 81, but is determined by the side oscillator 84 used in the side unit 80. The side oscillator 84, which has higher frequency than the DDS 81, can down-convert the signal in the feedback loop, i.e. frequency divider output signal, to lower frequencies, and a phase noise improvement can be realized.

Compared to the known offset loop structures shown in FIGS. 1 and 2, for the reference input of the main phase detector 71 of the main loop 70, a main reference signal source 62 with a good phase noise characteristic is used to achieve a better phase noise for lower offset frequencies. On the other hand, the generated chirp signal is linear because the reference clock of the DDS 81 (i.e. the side reference signal received from a side reference signal source 64) is stable compared to a fractional divider loop.

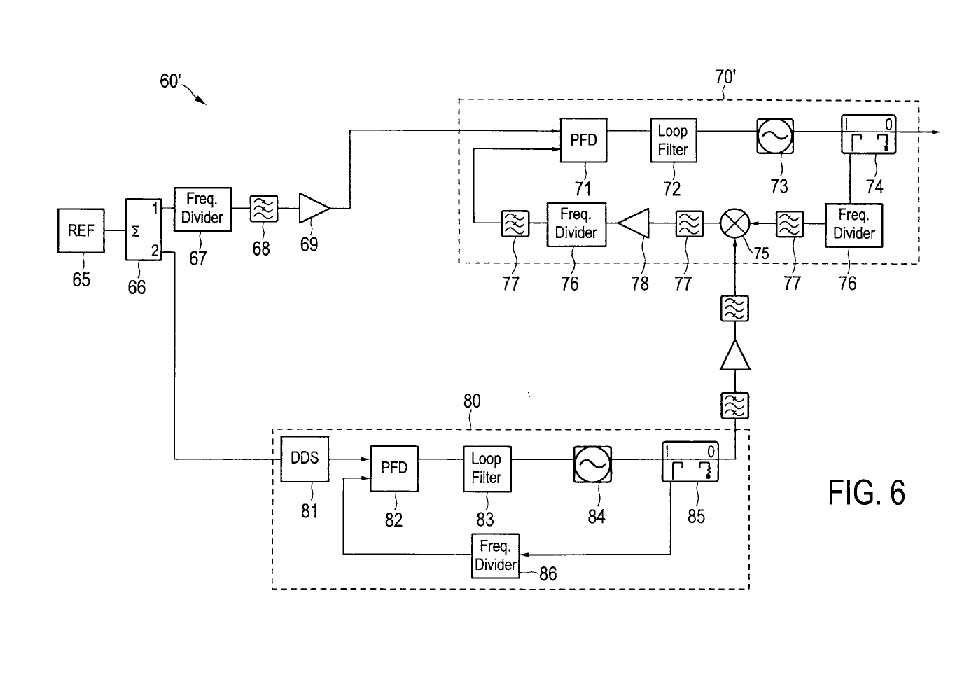

The reference sources 62 and 64 to the main unit 70 and the side unit 80 can be separated as shown in FIG. 5, but in an alternative embodiment a common reference source 65 can be used for both the main unit 70′ and the side unit 80 as provided in the second embodiment of a frequency synthesizer 60′ according to the present invention shown in FIG. 6. If the same reference source 65 is used, a signal splitter 66 can be used for providing the reference signal to the main unit 70′ (which may also be realized as main unit 70 shown in FIG. 5) and the side unit 80. Further, either a frequency divider 67 (as shown) or a frequency multiplier (not shown) is needed coupled to the input of at least one of the main unit 70′ and the side unit 80 in front of the respective phase detector input. Further, a low-pass filter 68 and an amplifier 69 are coupled in the same line after the frequency divider 67 (or frequency multiplier).

In the main unit 70′, one or more frequency dividers 76 may be used in the feedback loop. If the synthesizer has a broad bandwidth, frequency dividers can be required to scale the bandwidth down, otherwise the signal may exceed the locking range of the phase detector. Additional frequency dividers can degrade phase noise due to the increased division ratio. Further, if needed from a power leveling point of view (i.e. if enough power is needed for the frequency divider and/or for the phase detector) or spurious suppression (e.g. to suppress mixer spurs and harmonics), filters 77 and/or amplifiers 78 are additionally provided in the feedback loop. Still further, instead of couplers used as output units 74, 85, power dividers can be used. The frequency divider 86 of the side loop 80 can also be exchanged by a mixer provided with a oscillator signal from a local oscillator as shown in FIG. 2. In this way a phase noise improvement for the local oscillator signal of mixer 75 is achieved resulting in an overall phase noise improvement of the synthesizer output signal.

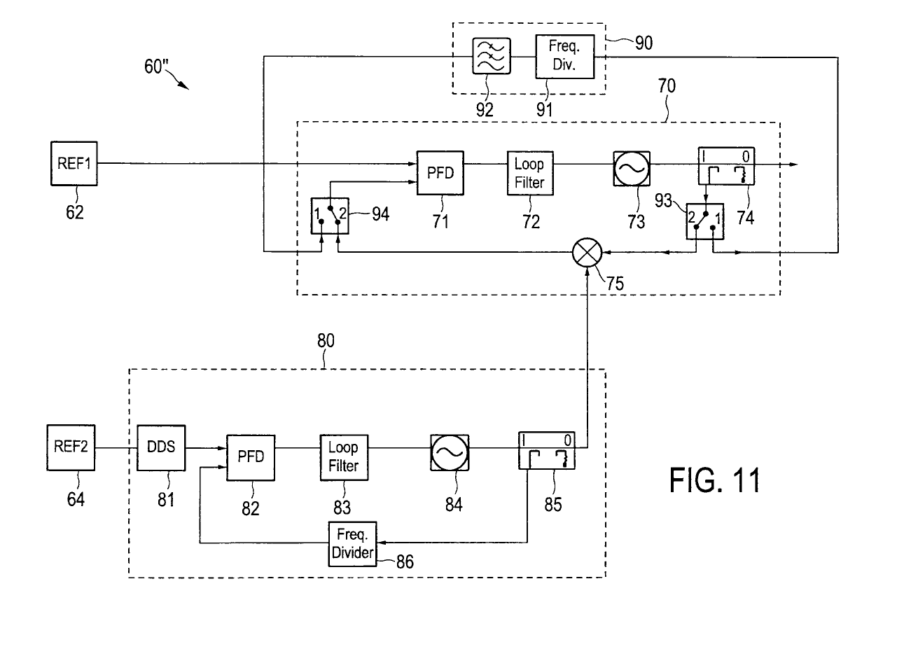

Still another embodiment of a frequency synthesizer 60″ according to the present invention is shown in FIG. 11, which is to a large extent identical to the embodiment of the synthesizer 60 shown in FIG. 5. If a large signal bandwidth is required, frequency dividers with higher division ratio should be used in order to limit the signal bandwidth at the input of the phase detector 71 for locking. However, using frequency dividers with high division rate can degrade the phase noise performance. To solve this, a locking mechanism can be added as shown in FIG. 11. Said locking mechanism comprises a locking unit 90 provided in parallel to the main unit 70. Said locking unit 90 includes a frequency divider 92a and a low pass filter 91. Further, two switching units 93, 94 are provided. The switching unit 93 is provided for switching the output of the main output unit 74 either onto the locking unit 90 (switching position 1) or the mixer 52 (switching position 2). The switching unit 94 is provided for switching either the signal from the main unit 90 (switching position 1) or the feedback signal from the mixer 52 (switching position 2) onto the second input of the phase detector 71. The locking unit 90 provides the initial locking when the switching units 93, 94 are in the switching position 1. After said locking, i.e. after switching the switching units to switching position 2, the feedback loop with the mixer 75 is used.

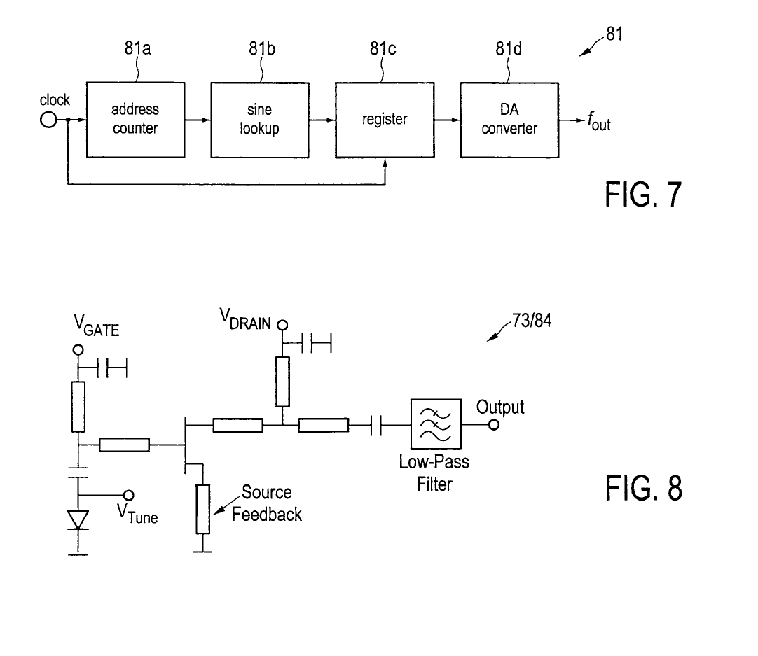

In the following, exemplary embodiments for essential elements of the proposed frequency synthesizer shall be briefly explained. These elements are generally known per se, i.e. various implementations and the function of those elements are generally known to the skilled person and can be found in various publications. The present invention is in no way limited to the implementations shown in FIGS. 7 to 10 and explained above, which implementations are only shown for illustrative purposes.

A DDS generates a harmonic signal from digital sample points. Thus, the frequency can be controlled very precisely by means of digital electronic. Actual limitations, which come from finite clock frequencies and converter resolution, are steadily reduced with the use of faster mixed signal circuits. An exemplary embodiment of a DDS 81 as described in Stelzer, A.; Kolmhofer, E.; Scheiblhofer, S., “Fast 77 GHz chirps with direct digital synthesis and phase locked loop”, Microwave Conference Proceedings, 2005, APMC 2005, Asia-Pacific Conference Proceedings, vol. 3, 4-7 Dec. 2005 is depicted in FIG. 7. An address counter 81a is permanently increased by a phase offset and points to a sine lookup table 81b that maps phase information to amplitudes. These values are latched by a register 81c and converted to an analog signal by a DA converter 81d. The sampling theorem and a realizable anti aliasing filter limit the maximum output frequency.

A voltage-controlled oscillator or VCO is an electronic oscillator designed to be controlled in oscillation frequency by a voltage input. The frequency of oscillation is varied by the applied DC voltage, while modulating signals may also be fed into the VCO to cause frequency modulation (FM) or phase modulation (PM); a VCO with digital pulse output may similarly have its repetition rate (FSK, PSK) or pulse width modulated (PWM). An exemplary embodiment of a voltage controlled oscillator for use as oscillator 73 and/or 84 as described in Koch S. et al. “140 GHz heterodyne receiver chipset for passive millimeter wave imaging applications”, IEEE Compound Semiconductor Integrated Circuit Symposium, CSICS 2009, Oct. 11-14, 2009, Greensboro, N.C., USA, is depicted in FIG. 8.

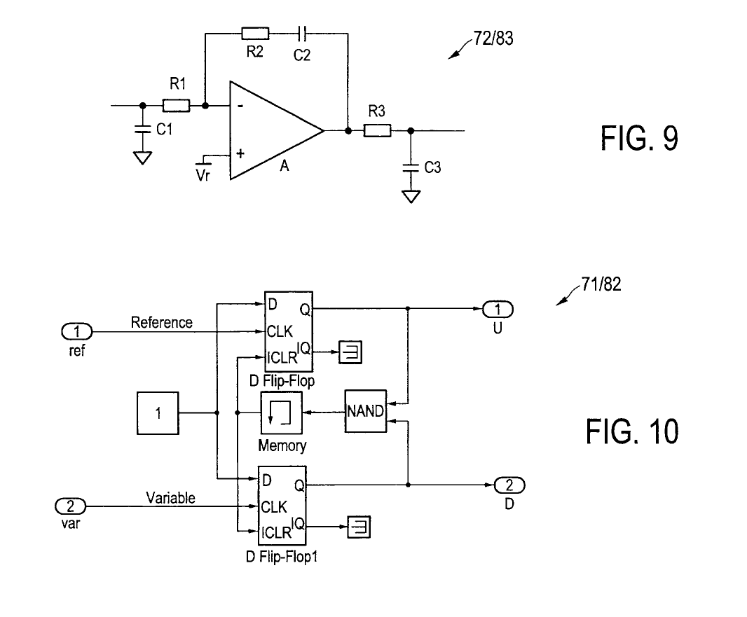

An exemplary embodiment of a loop filter (e.g. an active loop filter) for use as loop filter 72 and/or 83 is depicted in FIG. 9. This embodiment of the loop filter 72/83 includes an operational amplifier A, capacitors C1, C2, C3 and resistors R1, R2 connected as shown.

A phase frequency detector (PFD), in electronics, is a device which compares the phase of two input signals. It has two inputs which correspond to two different input signals, usually one from a voltage-controlled oscillator (VCO) and another from some external reference source. An exemplary embodiment of a phase frequency detector for use as phase detector 71 and/or 82 is depicted in FIG. 10. It has two outputs which instruct subsequent circuitry on how to adjust to lock onto the phase. In this embodiment the phase frequency detector is implemented by two flip-flops and a NAND gate.

The proposed frequency synthesizer can synthesize linear continuous frequency sweeps in microwave and millimeter wave frequencies. The synthesized frequency has low phase noise in lower and higher in-band offset frequencies. The frequency synthesizer has very fine resolution (Hz), which depends on the DDS performance. It is also capable of synthesizing multitude waveforms such as very linear, quadratic, cubic frequency chirps or deterministic deviations from linear frequency ramps. A high loop bandwidth provides a fast switching time and good frequency stability against mechanical vibrations.

In summary, with the present invention a very linear frequency sweep can be achieved, particularly due to the digital frequency generation from the DDS. A higher frequency signal can be generated for the local oscillator input of the mixer of the main unit due to the use of a hybrid DDS/PLL loop as side unit. Thus, the RF signal can be down-converted to lower IF frequencies resulting in a phase noise improvement. Further, because the DDS output is not connected to the phase detector input in the main loop, as is the case in some known embodiments, a very stable reference frequency (e.g. from an OCXO) can be used for the phase detector input of the main loop. This also provide for an additional phase noise improvement.

The invention has been illustrated and described in detail in the drawings and foregoing description, but such illustration and description are to be considered illustrative or exemplary and not restrictive. The invention is not limited to the disclosed embodiments. Other variations to the disclosed embodiments can be understood and effected by those skilled in the art in practicing the claimed invention, from a study of the drawings, the disclosure, and the appended claims.

In the claims, the word “comprising” does not exclude other elements or steps, and the indefinite article “a” or “an” does not exclude a plurality. A single element or other unit may fulfill the functions of several items recited in the claims. The mere fact that certain measures are recited in mutually different dependent claims does not indicate that a combination of these measures cannot be used to advantage.

Any reference signs in the claims should not be construed as limiting the scope.

1. Frequency synthesizer comprising:
i) a main unit comprising:
a main phase detector that compares the phase and/or frequency of a mixer output signal received from a main feedback loop of the main unit to the phase of a fixed-frequency main reference signal to obtain a main control signal,
a main oscillator that generates a main synthesized frequency output signal representing the frequency synthesizer output signal based on said main control signal, and
a mixer that mixes said main synthesized frequency output signal with a side synthesized frequency output signal to obtain said mixer output signal, and
ii) a side unit that generates said side synthesized frequency output signal based on a fixed-frequency side reference signal comprising:
a frequency signal generation unit that provide a linear frequency sweep signal or a fixed-frequency control signal at a fine frequency resolution from said fixed-frequency side reference signal, and
a side oscillator that generates said side synthesized frequency output signal based on said frequency sweep signal or said fixed-frequency control signal.

2. Frequency synthesizer as claimed in claim 1,
wherein said frequency signal generation unit comprises a direct digital synthesizer that generates a DDS signal representing said linear frequency sweep signal or a fixed-frequency control signal from said fixed-frequency side reference signal,
a side phase detector that compares the phase and/or frequency of said DDS signal received from a side feedback loop of the side unit to the phase of said fixed-frequency side reference signal, and
a side frequency divider that frequency divides a side synthesized frequency output signal to obtain said frequency divider output signal,
wherein said side oscillator generates said side synthesized frequency output signal based on said side control signal.

3. Frequency synthesizer as claimed in claim 1,
further comprising a main reference signal provision unit that provides said fixed-frequency main reference signal and a side reference signal provision unit that provides said fixed-frequency side reference signal.

4. Frequency synthesizer as claimed in claim 1,
further comprising a common reference signal provision unit that provides a common fixed-frequency reference signal for use as said fixed-frequency main reference signal and said fixed-frequency side reference signal.

5. Frequency synthesizer as claimed in claim 1,
wherein said main unit further comprises a main loop filter coupled between said main phase detector and said main oscillator for filtering said main control signal.

6. Frequency synthesizer as claimed in claim 2,
wherein said side unit further comprises a side loop filter coupled between said side phase detector and said side oscillator for filtering said side control signal.

7. Frequency synthesizer as claimed in claim 1,
wherein the output of said side oscillator is coupled to said mixer for providing said side synthesized frequency output signal to said mixer.

8. Frequency synthesizer as claimed in claim 1,
wherein said main unit further comprises a main frequency divider coupled between said main oscillator and said mixer and/or between said mixer and said phase detector that frequency divides said main synthesized frequency output signal and/or said mixer output signal.

9. Frequency synthesizer as claimed in claim 1,
wherein said main unit further comprises a main feedback filter and/or a feedback amplifier coupled between said main oscillator and said mixer and/or between said mixer and said phase detector that filters and/or amplifies, respectively, said main synthesized frequency output signal and/or said mixer output signal.

10. Frequency synthesizer as claimed in claim 4,
wherein said main unit and/or said side unit further comprises an input frequency divider or an input frequency multiplier coupled to the input of the respective phase detector wherein said input frequency divider or said input frequency multiplier, respectively, frequency divides or frequency multiplies, respectively, said common reference signal before providing it to the respective phase detector.

11. Frequency synthesizer as claimed in claim 4,
wherein said main unit and/or said side unit further comprises an input filter and/or an input amplifier coupled to the input of the respective phase detector wherein said input filter and said input amplifier, respectively, filter and/or amplify, respectively, said common reference signal before providing it to the respective phase detector.

12. Frequency synthesizing method comprising:
i) in a main loop:
comparing the phase and/or frequency of a mixer output signal received from a main feedback loop of the main loop to the phase of a fixed-frequency main reference signal to obtain a main control signal,
generating a main synthesized frequency output signal representing the frequency synthesizer output signal based on said main control signal, and
mixing said main synthesized frequency output signal with a side synthesized frequency output signal to obtain said mixer output signal, and
ii) in a side loop for generating said side synthesized frequency output signal based on a fixed-frequency side reference signal:
providing a linear frequency sweep signal or a fixed-frequency control signal at a fine frequency resolution from said fixed-frequency side reference signal, and
generating said side synthesized frequency output signal based on said frequency sweep signal or said fixed-frequency control signal.

13. Frequency synthesizing method as claimed in claim 12, comprising in the side loop the steps of:
generating a DDS signal from a fixed-frequency side reference signal,
comparing the phase and/or frequency of a frequency divider output signal received from said side feedback loop of the side loop to the phase of said DDS signal,
generating said side synthesized frequency output signal based on said side control signal, and
frequency dividing the side synthesized frequency output signal to obtain said frequency divider output signal.

14. Frequency synthesizer comprising:
i) a main unit comprising:
a main phase detection means for comparing the phase and/or frequency of a mixer output signal received from a main feedback loop of the main unit to the phase of a fixed-frequency main reference signal to obtain a main control signal,
a main oscillation means for generating a main synthesized frequency output signal representing the frequency synthesizer output signal based on said main control signal, and
a mixing means for mixing said main synthesized frequency output signal with a side synthesized frequency output signal to obtain said mixer output signal, and
ii) a side unit for generating said side synthesized frequency output signal based on a fixed-frequency side reference signal comprising:
a frequency signal generation means for providing a linear frequency sweep signal or a fixed-frequency control signal at a fine frequency resolution from said fixed-frequency side reference signal, and
a side oscillation means for generating said side synthesized frequency output signal based on said frequency sweep signal or said fixed-frequency control signal.
